(19) United States
(12) Patent Application Publication
(10) Pub. No.: US 2002/0142107 A1
(43) Pub. Date: Oct. 3, 2002

(54) Fabrication of customized, composite, and alloy-variant components using closed-loop direct metal deposition

(76) Inventors: Jyoti Mazumder, Ann Arbor, MI (US); Dwight Morgan, Rochester, MI (US); Timothy W. Skszek, Saline, MI (US)

Correspondence Address: GIFFORD, KRASS, GROH, SPRINKLE, ANDERSON & CITKOWSKI, PC, 280 N OLD WOODARD AVE, SUITE 400, BIRMINGHAM, MI, 48009, US

(21) Appl. No.: 09/917,096

(22) Filed: Jul. 27, 2001

Related U.S. Application Data
(60) Provisional application No. 60/221,251, filed on Jul. 27, 2000.

(51) Int. Cl. C23C 14/30

(52) U.S. Cl. 427/596; 427/8

(57) ABSTRACT

A laser-assisted, direct metal deposition (DMD™), preferably in a closed-loop arrangement, is used to fabricate designed articles and tools such as molds and tools with improved properties. According to the method of the invention, a substrate is provided having a surface, onto which a layer of a material is deposited having the desired characteristic using the laser-assisted DMD process. In different embodiments, the substrate/layer combination may be tailored for improved wear resistance, thermal conductivity, density/hardness, corrosion and/or resistance to corrosion, oxidation or other undesirable effects. Alternatively, the layer of material may be tailored to have a phase which is different from that of the substrate. In particular, the layer material itself may be chosen to promote a phase which is different from that of the substrate. In the preferred embodiment, a closed-loop, laser-assisted DMD process is deployed to build the substrate on an incremental basis. To enhance throughput, the substrate and/or outer layer(s) of material may be fabricated using a robotic closed-loop DMD arrangement. In concert with the improvements made possible through the tailored outer layer(s), the method may further include the step of incorporating one or more conformal cooling channels within the component or the formation of one or more conductive heat sinks or thermal barriers during the DMD fabrication of the component itself.

### REFERENCE TO RELATED APPLICATION

This application claims priority from U.S. provisional patent application Serial No. 60/221,251, filed Jul. 27, 2000, the entire contents of which are incorporated herein by reference.

### FIELD OF THE INVENTION

This invention relates generally to additive manufacturing and, in particular, to the fabrication of customized, composite, and alloy-variant components using closed-loop, laser-based direct metal deposition (DMD™).

### BACKGROUND OF THE INVENTION

The desired functionality of dies, molds and three-dimensional components depends on service conditions and applications. Many of these components are expensive yet rendered obsolete due to modest changes in design and/or operating conditions. The cost of tooling (i.e., molds and dies) has also prevented mass customization of cast or molded products for local markets.

Three-dimensional components adaptable to various operating needs have the potential of substantially reducing tooling costs and minimizing lead-time while allowing rapid customization of current and obsolete tooling, as well as the salvaging of previously scrapped dies. In particular, techniques such as closed-loop direct metal deposition and laser clad tailored surfaces can be utilized to design and tailor tools and components for specific applications.

Stamping, injection molding and die casting often require modest changes during the design process for improved aerodynamics, last-minute engineering functional changes, or aesthetic considerations. Closed-loop, direct metal deposition can realize such changes on an existing tool with proper alloy matching (often referred as color matching in the die repair industry) and close dimensional tolerance. The technique will lead to cost and lead-time savings by reducing post processing cost and reconfiguring the original tool.

Surface wear properties often requires hard but brittle materials, whereas the overall component itself may require more ductile material for toughness during service life. A method of metallurgically bonding a brittle surface to a tough substrate should offer a wide array of choices for designers.

Temperature rise during operation is one of the reasons for die distortion. Asymmetric thermal loading and resultant stress distribution and thermal fatigue are a few of the additional causes contributing to failure. The operating life of a component increases with proper thermal management of the component. Carefully designed conformal cooling channels and heat sinks in a mold will substantially reduce the cycle time of the component leading to increased profitability for the users of “designer dies.”

Lightweight materials, such as aluminum, are preferred for energy conservation, easy of die change, and improved thermal conductivity, but aluminum components often have poor wear resistance. A composite design, with thin hard surface and lighter interior will satisfy both energy conservation and increased service life due to reduced surface wear.

For large three-dimensional objects such as stamping tools, a reconfiguration method capable of localized processing on a stationary object has distinct advantages with respect to work handling and accuracy, which should lead to substantial cost savings. In such situations, a low-cost alloy can be used for the majority of the die, where load bearing is the key requirement, while a high-cost alloys can be deposited strategically on to the low cost alloy where wear, cutting, and abrasive action is needed to form the complex shape of metal-stamped parts.

### SUMMARY OF THE INVENTION

Broadly, this invention utilizes a laser-assisted, direct metal deposition (DMD™), preferably in a closed-loop arrangement, to fabricate designed articles and tools such as molds and tools with improved properties. According to the method, a substrate is provided having a surface, onto which a layer of a material is deposited having the desired characteristic using the laser-assisted DMD process.

In different embodiments, the substrate/layer combination may be tailored for improved wear resistance, thermal conductivity, density/hardness, corrosion and/or resistance to corrosion, oxidation or other undesirable effects. Alternatively, the layer of material may be tailored to have a phase which is different from that of the substrate. In particular, the layer material itself may be chosen to promote a phase which is different from that of the substrate.

In the preferred embodiment, a closed-loop, laser-assisted DMD process is deployed to build the substrate on an incremental basis. To enhance throughput, the substrate and/or outer layer(s) of material may be fabricated using a robotic closed-loop DMD arrangement. In concert with the improvements made possible through the tailored outer layer(s), the method may further include the step of incorporating one or more conformal cooling channels within the component or the formation of one or more conductive heat sinks or thermal barriers during the DMD fabrication of the component itself.

### BRIEF DESCRIPTION OF THE DRAWINGS

FIG. 1 shows a direct metal deposition (DMD) system with stationary beam and moving substrate;

FIG. 2 is a close-up view of the deposition head and optical feedback monitoring system;

FIG. 3 illustrates a robotic embodiment of DMD;

FIG. 4 illustrates how a DMD system is improved with sensors and high-speed communications;

FIG. 5A is a cross-sectional drawing showing the way in which a hardened material can be used to encase a softer and/or more thermally conductive material utilizing direct metal deposition;

FIG. 5B is a drawing which shows the planes along which the cross-section of FIG. 5A were taken;

FIG. 6A shows an injection molding die with conventional cooling channels;

FIG. 6B shows an injection molding die with conformal cooling channels made possible through the method of this invention;

FIG. 7 is a bar chart which provides a comparative analysis of core heating time utilizing direct metal deposition in lightweight, solid, hollow and aluminum structures;

FIG. 8 is a bar chart which provides a comparative analysis of cavity heating time utilizing direct metal deposition in lightweight, solid, hollow and aluminum structures;

FIG. 9 plots temperature vs. elapsed time for aluminum vs. cavity structures produced using direct metal deposition;

FIG. 10 plots temperature vs. elapsed time for aluminum vs. core structures produced using direct metal deposition;

FIG. 11 is a plot of temperature vs. time for aluminum vs. lightweight cavity structures fabricated using direct metal deposition;

FIG. 12 is a plot of temperature vs. time for aluminum vs. lightweight core structures fabricated using direct metal deposition;

FIG. 13 is a plot of temperature vs. time for aluminum vs. a different lightweight structure fabricated using direct metal deposition with respect to cavity structures; and

FIG. 14 is a plot of temperature vs. time for aluminum vs. a different lightweight structure fabricated using direct metal deposition with respect to core structures.

### DETAILED DESCRIPTION OF THE INVENTION

As described in U.S. Pat. No. 6,122,564, the entire contents of which are incorporated herein by reference, a closed-loop direct metal deposition (DMD™) process may be employed to fabricate three-dimensional components utilizing the tool path generated by a suitably equipped CAD/CAM package. A complex shape is generated by delivering desired material (i.e., metal/alloy powder or wire) to a laser-melted pool, with a finished part being created by changing the relative position of the laser beam and the substrate. The system may use a stationary beam and material delivery system in conjunction with a moving substrate, or the beam and material delivery system may be moved relative to a stationary substrate.

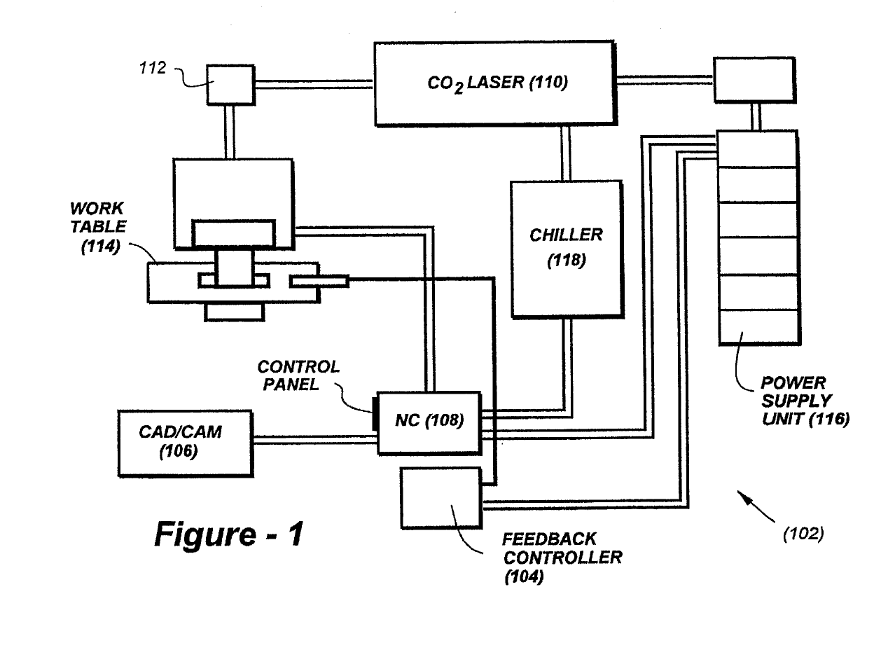

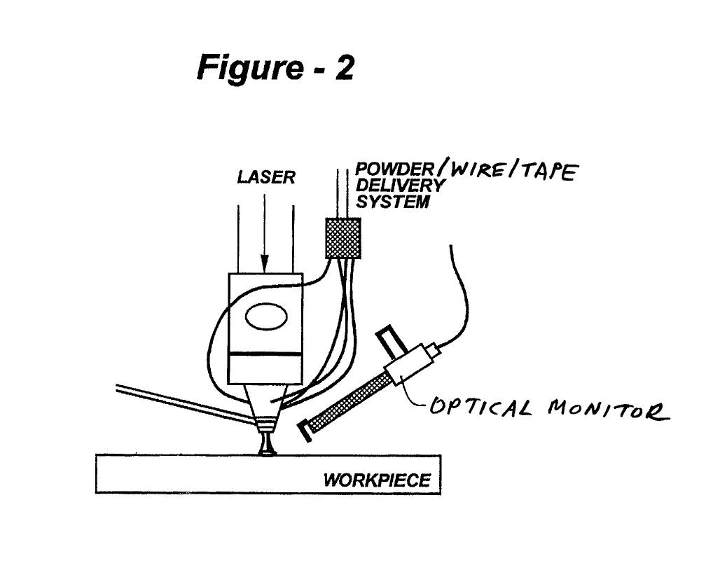

FIG. 1 shows a laser-aided, computer-controlled DMD system schematically at 10 being used to apply layers of material 20 on a substrate 30 to fabricate an object or cladding. The system is preferably equipped with feedback monitoring, better seen in FIG. 2, to control of the dimensions and overall geometry of the fabricated article. The geometry of the article is provided by a computer-aided design (CAD) system.

The deposition tool path is generated by a computer-aided manufacturing (CAM) system for CNC machining with post-processing software for deposition, instead of software for removal as in conventional CNC machining. CAM software interfaces with a feedback controller 104. These details of the laser-aided, computer controlled direct material deposition system can be found in U.S. Pat. No. 6,122,564, and are not all explicitly shown in FIGS. 1 and 2.

The factors that affect the dimensions of material deposition include laser power, beam diameter, temporal and spatial distribution of the beam, interaction time, and powder flow rate. Adequate monitoring and control of laser power, in particular, has a critical effect on the ability to fabricate completed parts and products with complex geometries and within control tolerances. Accordingly, the feedback controller 80 of the direct material deposition system typically cooperates directly with the numerical controller 90, which, itself, controls all functions of the direct material deposition system, including laser power.

The laser source 110 of the DMD system is mounted above the substrate 30 and a layer of material 20 is deposited according to the description of the object. The laser has sufficient density to create a melt pool with the desired composition of substrate or previously deposited layer and cladding powder. The cladding powder, typically metallic, is sprayed on the substrate preferably through a laser spray nozzle with a concentric opening for the laser beam, as described in U.S. Pat. No. 4,724,299, so that the powder exits the nozzle co-axially with the beam.

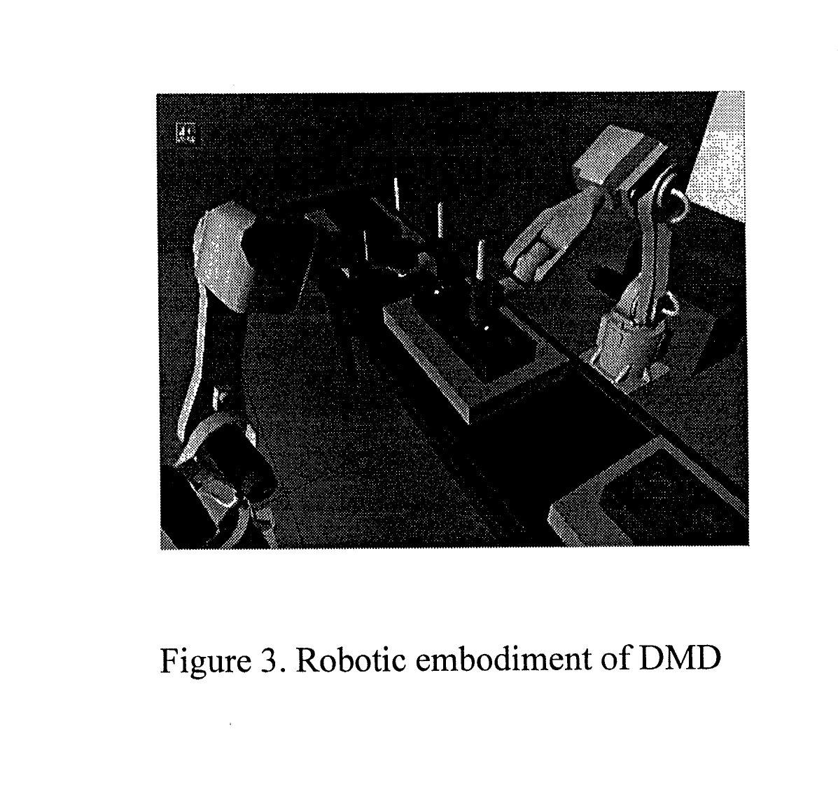

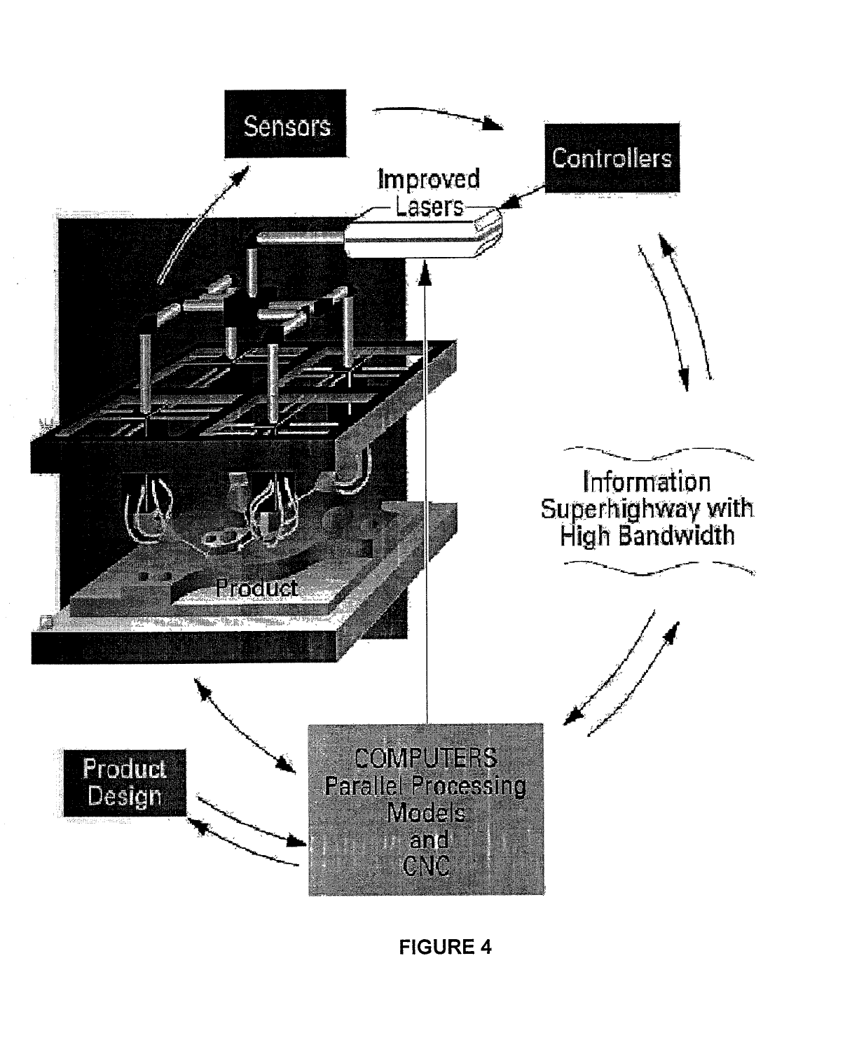

A numerical controller 108 controls all operating components of the DMD system of FIG. 1, including the operating conditions of the laser, receiving direction from the CAD/ CAM system 106 for building the part or product. The numerical controller 108 also receives feedback control signals from the feedback controller 104 to adjust laser power output, and further controls the relative position of the substrate and laser spray nozzle. The CAD/CAM system 106 is equipped with software which enables it to generate a path across the substrate for material deposition. Other refinements, such as robotic handling and multiple deposition heads for simultaneous deposition onto a die surface, are depicted in FIGS. 3 and 4, respectively.

According to this invention, the closed-loop direct metal deposition (CLDMD™) process is used to deposit desired alloys on an existing surface of a die or other component. To satisfy a completely new design, or to change an existing design, the required area on the object can either be machined off to a desired shape and subsequently built over using CLDMD directly from the new CAD data or built over the existing surface, if the new design can accommodate it.

The optical feedback loop preferably maintains fabrication tolerances to within 25 to 150 microns. Material can be delivered at the laser melted pool by various means, including pneumatic powder delivery, wire feed or tape feed. Either the same material as the substrate or any other metallurgically compatible material can be deposited by this process. By proper selection of the deposited material, properties can be tailored to application requirement in addition to the geometric requirements. Surface oxidation during the process is minimized by inert shielding gas delivered either through the concentric nozzle or separate shielding nozzle. Under special circumstances, the process may be carried out in an inert atmosphere chamber.

With proper selection of the deposit alloy system, a functional component can be designed and fabricated with tailored properties such as improved wear resistance within the limitation of the available alloy systems. A preferred strategy for surface modification for tailored surface is as follows:

### Selection of Phases

Face-centered cubic (F.C.C.) structure with large number of available slip planes will be beneficial for ductility, whereas brittle non-cubic phases exhibiting a limited number of available slip planes will promote hardness and wear resistance. A combination of FCC and non-FCC, with duplex phases, may be used to provide adequate toughness during service with reasonable wear resistance.

### Selection of Elements

A proper choice of elements is important for promoting certain phases, as well as protecting against chemical degradation. For example, chromium promotes body-centered cubic (B.C.C.) phase for ferrous alloys, whereas chromium oxide (Cr₂O₃) forms a passive surface layer to inhibit corrosion at temperature up to 800° C. Reactive elements such as yttrium and hafnium are known to stabilize Al₂O₃ at temperatures above 800° C., leading to high-temperature oxidation resistance.

### Selection of Process Parameters

Process parameters control the cooling rate, which controls the phase transformation kinetics. Therefore, the process parameters should be carefully selected to promote the desired phases. Inherent high cooling rates and strong convection associated with laser melting and solidification of CLDMD promotes atom trapping leading to extended solid solution. These non-equilibrium syntheses are utilized to dissolve low solubility material such as Y and Hf.

### Example 1

### Wear Management

An example will now be presented for tool wear management. Broadly, the process preferably includes the deposition of a Fe—Cr—W—C alloy onto a cheaper steel substrate. The chromium provides a BCC matrix, whereas the WC will provide hard M₆C carbide phases. Fe—Cr—W—C carbon system has demonstrated that significantly better wear resistance compared to Commercial alloy such as Stellite 6. When tested under same condition with a block on cylinder machine scar width for Stellite 6 exceeded 1.5 mm whereas that for the designed alloy was below 0.5 mm.

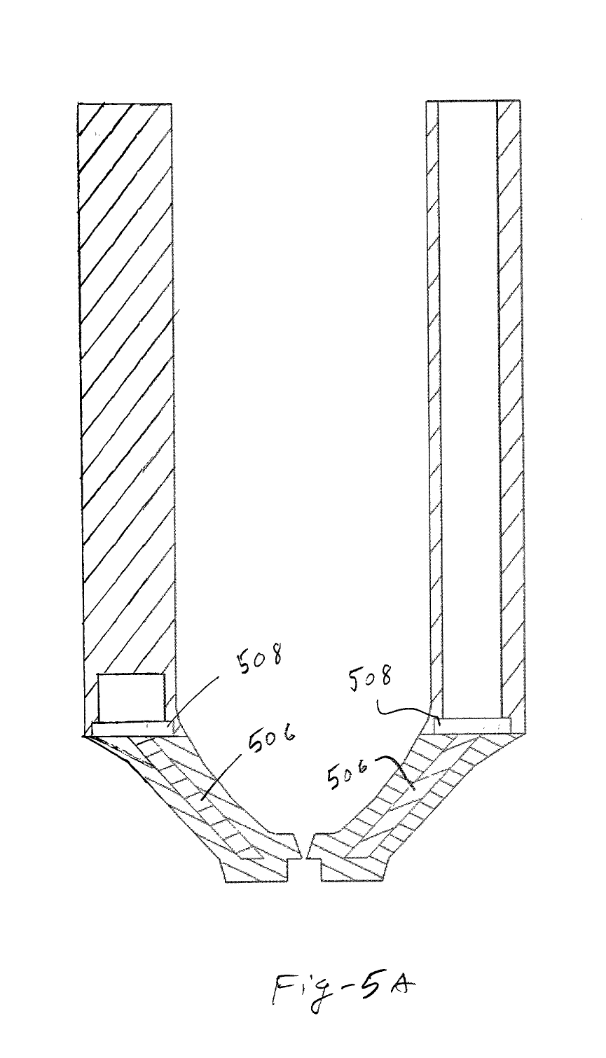

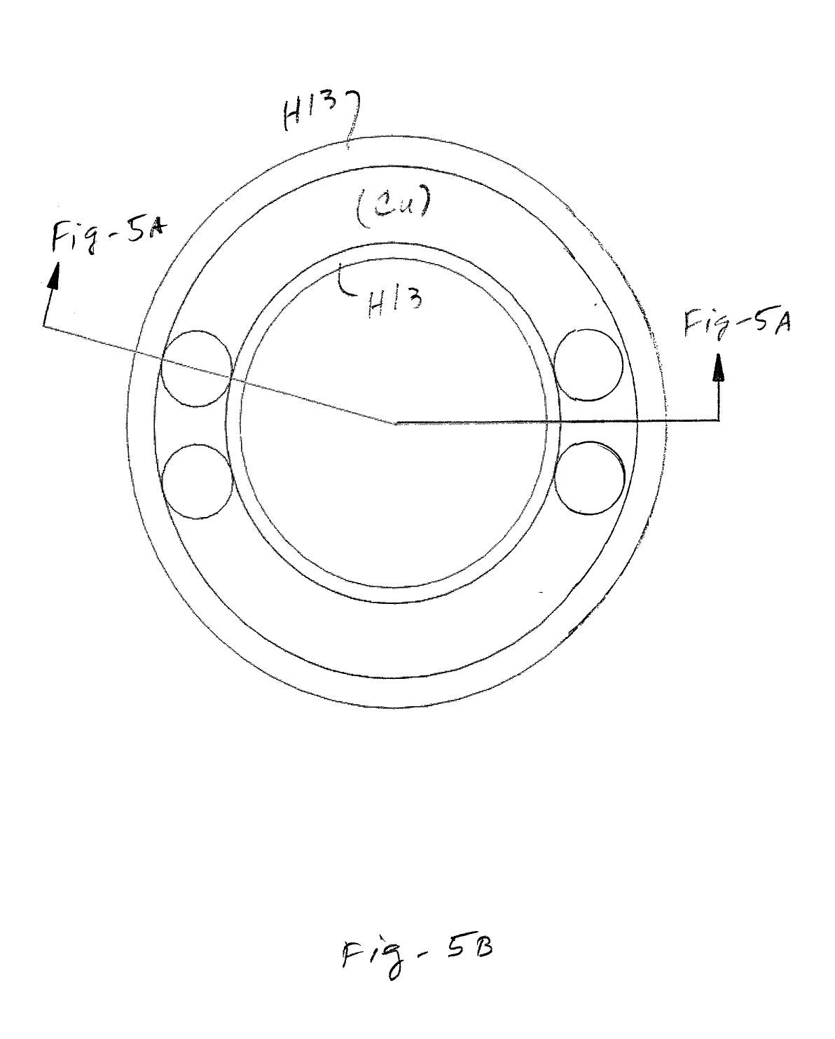

FIGS. 5A and 5B depict a laminate nozzle fabricated with H13 and Copper. In general, a nozzle base is machined which incorporates two waterline circuits which protrude into a cylindrical groove 506 machined into the end of the nozzle detail. A thermally conductive “loose piece” washer 508 is then placed over the premachined cylindrical groove, covering it during the DMD process.

A Cu/H13 laminate structure is fabricated on top of the premachined assembly (nozzle base & cap). The DMD laminate volume is approximately 1 in³. The nozzle tip can be heated/cooled by transferring heat from the thermal fluid through the “loose piece cap” and DMD copper laminate structure. Components of this type are used extensively in injection molding machines but are often subjected to wear and thermal damage. This design, based on DMD, exhibits improved wear resistance due to the H13 surface complemented by efficient cooling through the copper, thus reducing the temperature while it is subjected to a high-wear environment.

### Example 2

### Thermal Management

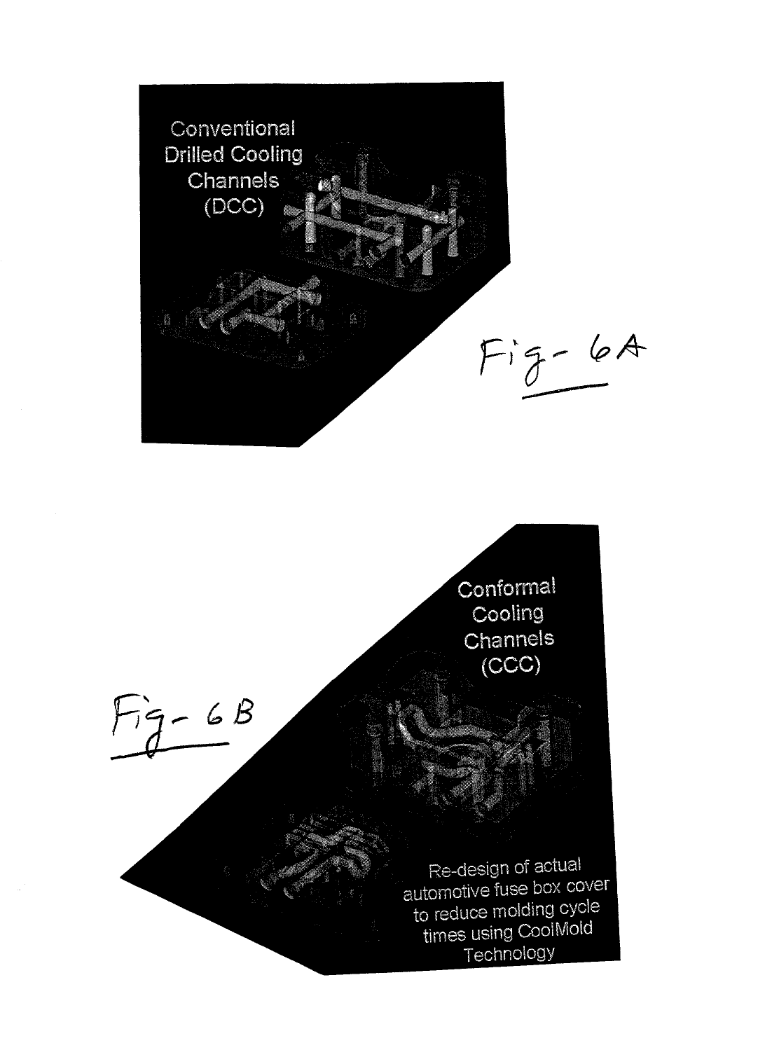

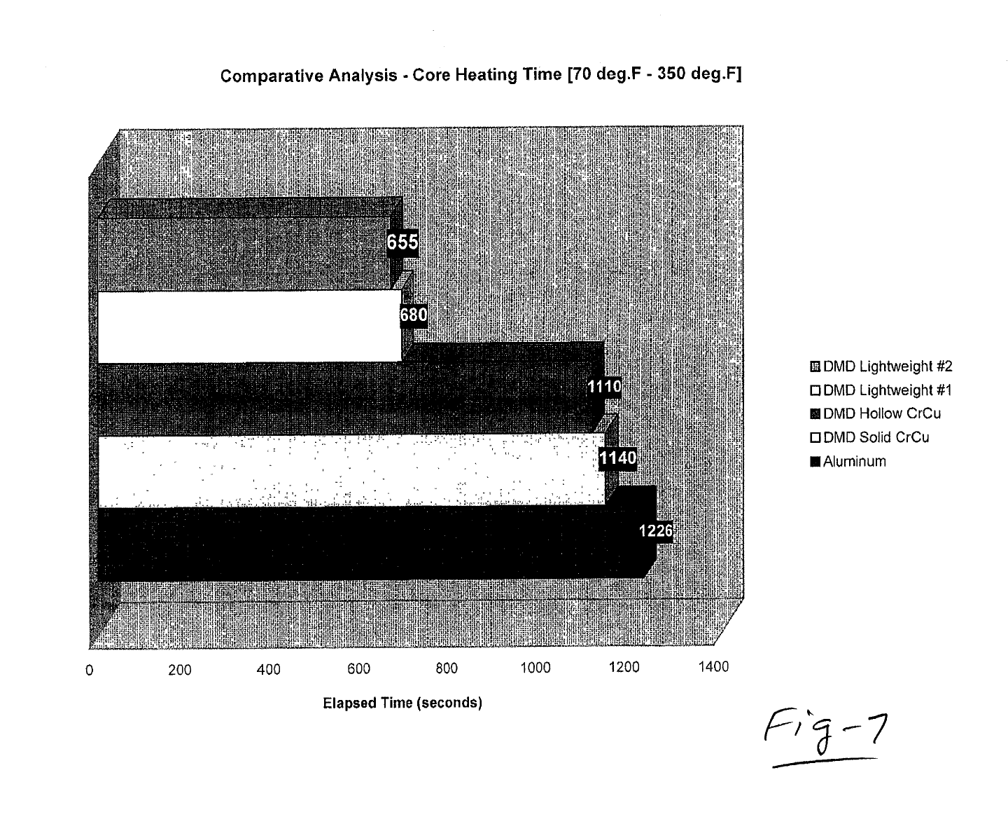

The capabilities of CLDMD can also be utilized for improved thermal management of a tool or other component. Firstly, conductive material such as copper can be incorporated inside a tool at critical points as heat sink. Secondly, a conformal cooling channel can be incorporated within the die leading to improved heat extraction during service compared to presently used straight-line cooling channels in injection molding dies. FIG. 6A shows an injection molding die with conventional cooling channels; FIG. 6B shows an injection molding die with conformal cooling channels according to this invention. Pressure and temperature sensors can also be incorporated within the tool during CLDMD process so as to impart thermal management. Improved thermal management reduces the cycle time of an injection mold or a die cast mold leading to substantial cost savings.

Theoretical calculations for cycle time using Moldflow analysis for the die shown in FIGS. 6A and 6B show that a 26% time savings is possible through combined conformal cooling and copper inserts. Comparative time savings for different geometries are provided in the table below. Note in the table that higher the curvature of the part such as U-plate, higher the time saving. Recently, in an initial injection molding test carried out without any optimized parameter of the relay cover die only with conformal cooling fabricated by DMD exhibited more than 8% time savings.

| | St. Line Cooling | Conformal Cooling | |
|---|---|---|---|
| Geometry | (sec.) | (sec.) | % Saving |
| Semi-cylinder | 6.6 | 4.1 | 38 |
| U Plate | 10.4 | 3.4 | 67 |
| Hemisphere | 14 | 5.4 | 61 |
| Relay Cover | 6.1 | 4.5 | 26 |

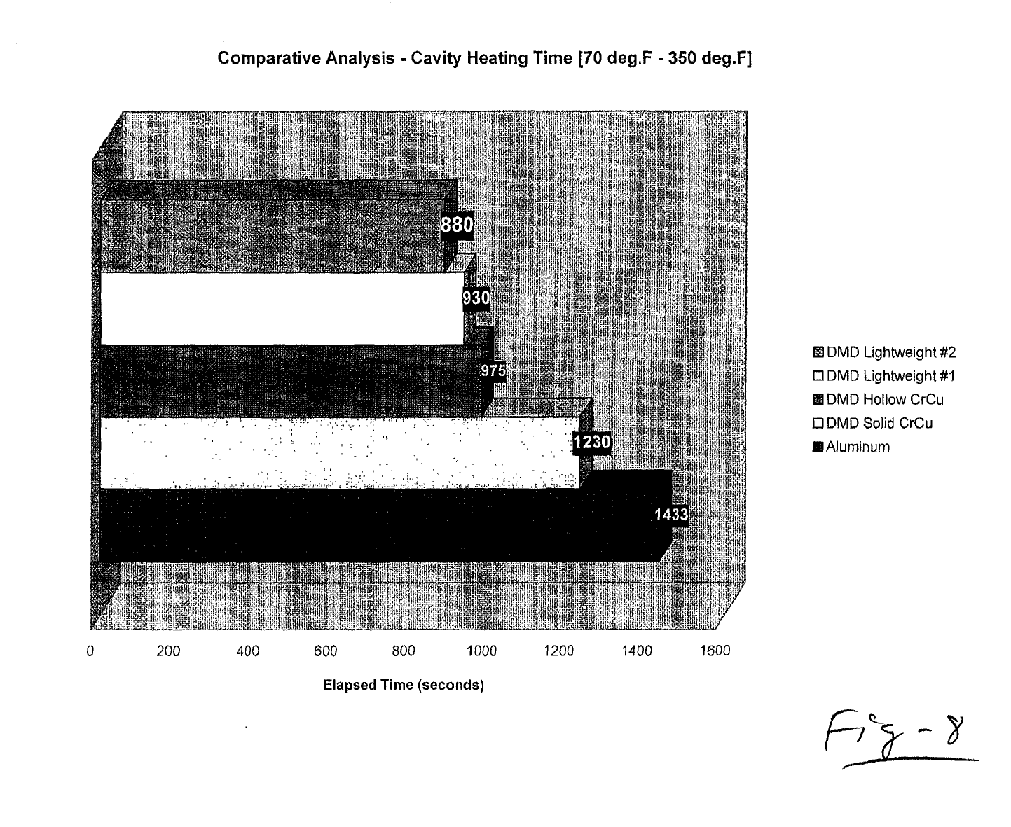

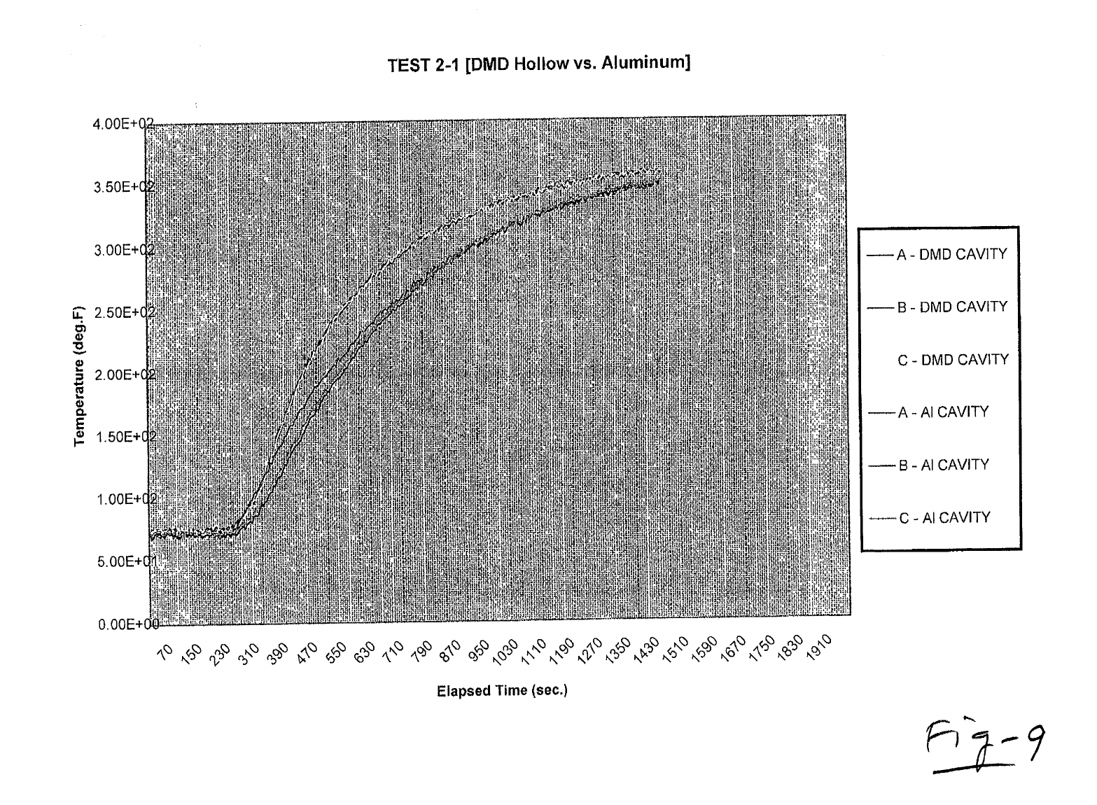

FIGS. 7 and 8, labeled “comparative analysis” show core and cavity heating time for dies fabricated by DMD using Cu-Cr substrate and hollow dies with thermally conductive pins for improved thermal management as compared to present, industry standard aluminum molds for injection molding. In particular, FIG. 7 is a bar chart which provides a comparative analysis of core heating time utilizing direct metal deposition in lightweight, solid, hollow and aluminum structures. FIG. 8 is a bar chart which provides a comparative analysis of cavity heating time utilizing direct metal deposition in lightweight, solid, hollow and aluminum structures. These bar charts clearly shows the rapid thermal response for the dies fabricated by DMD using the improved thermal management scheme.

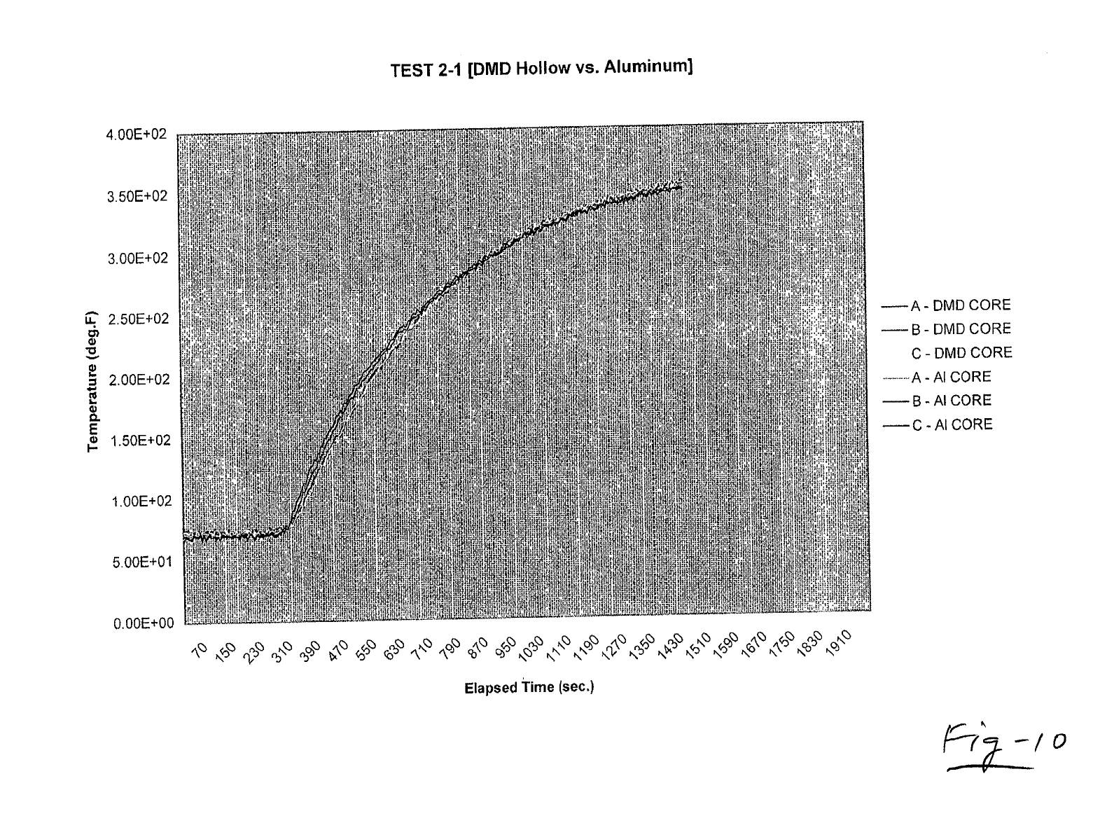

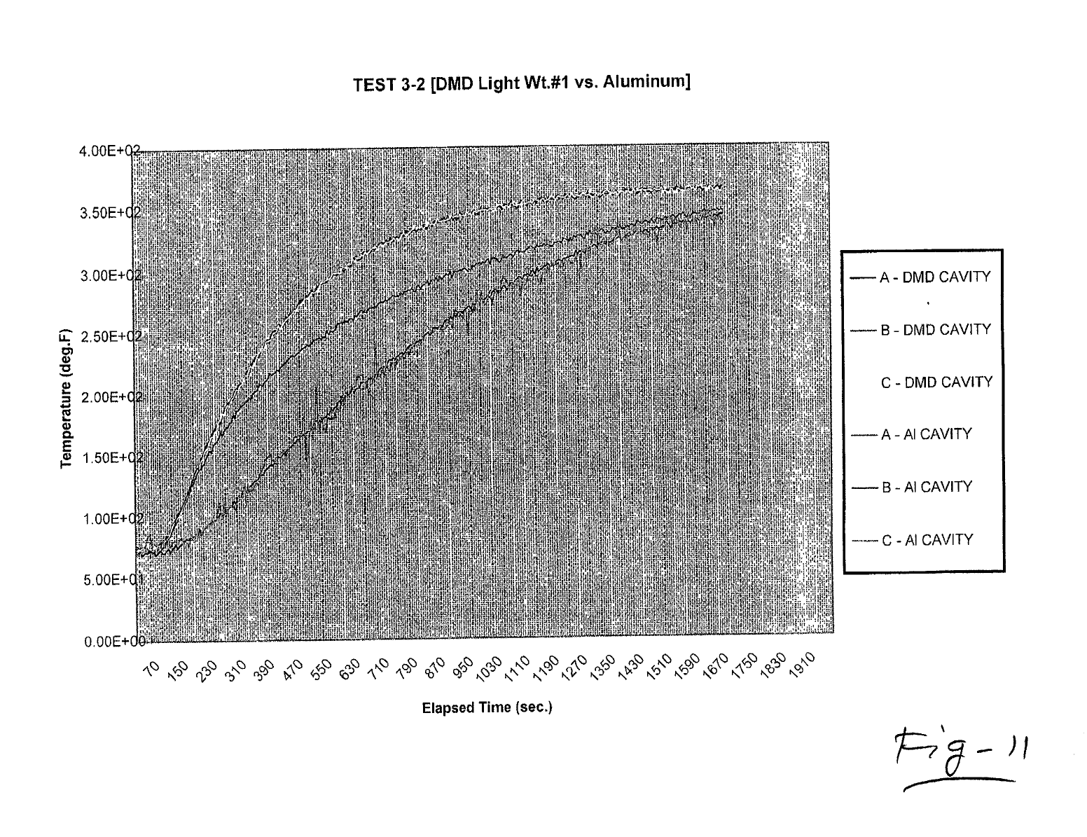

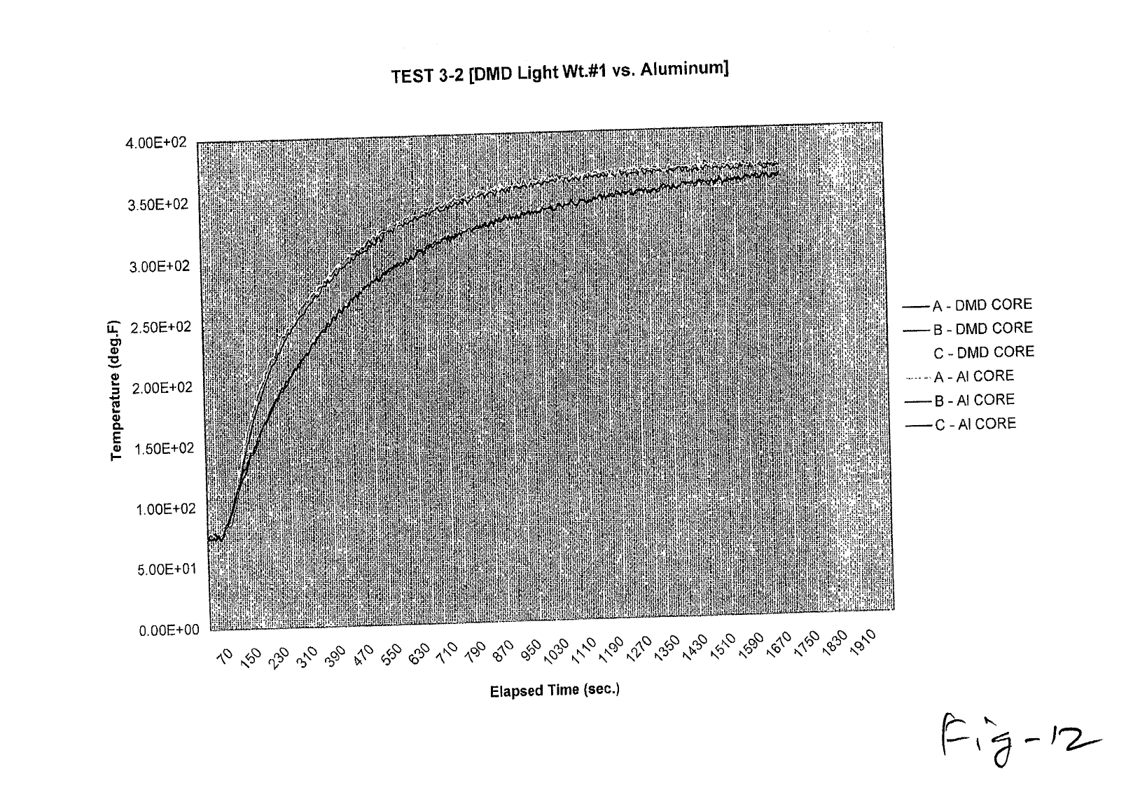

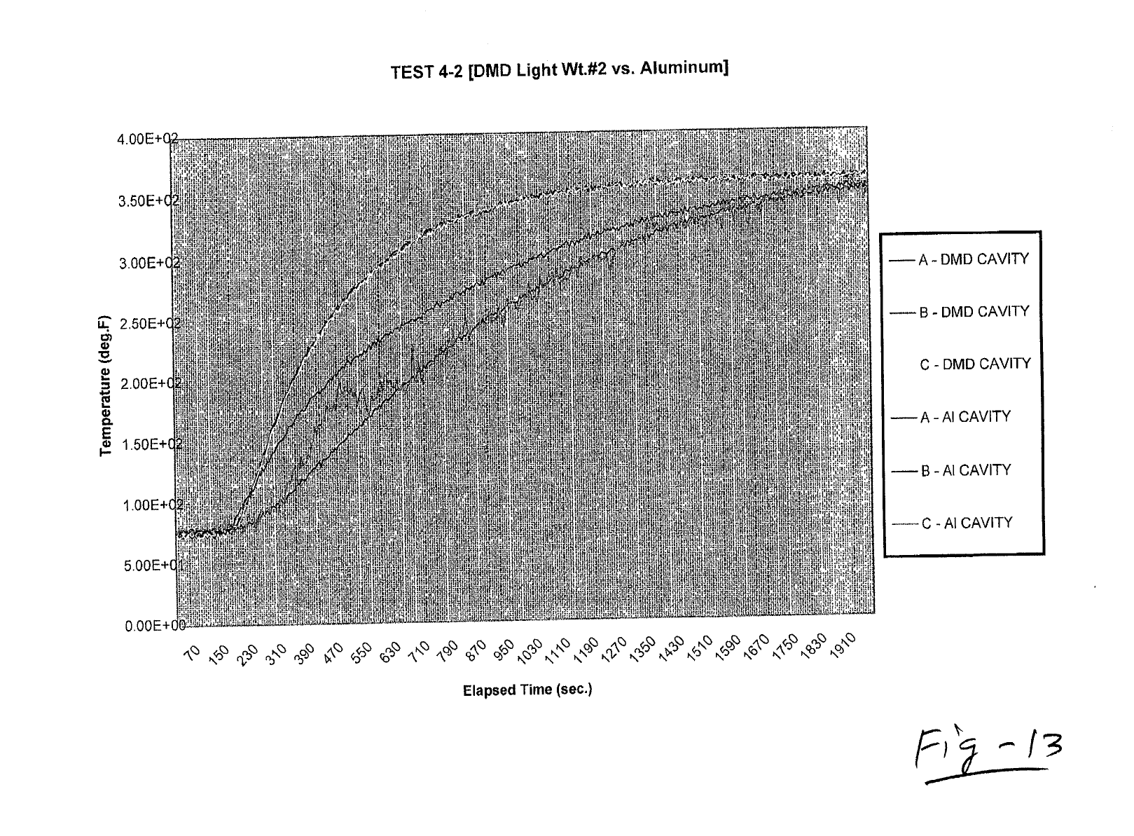

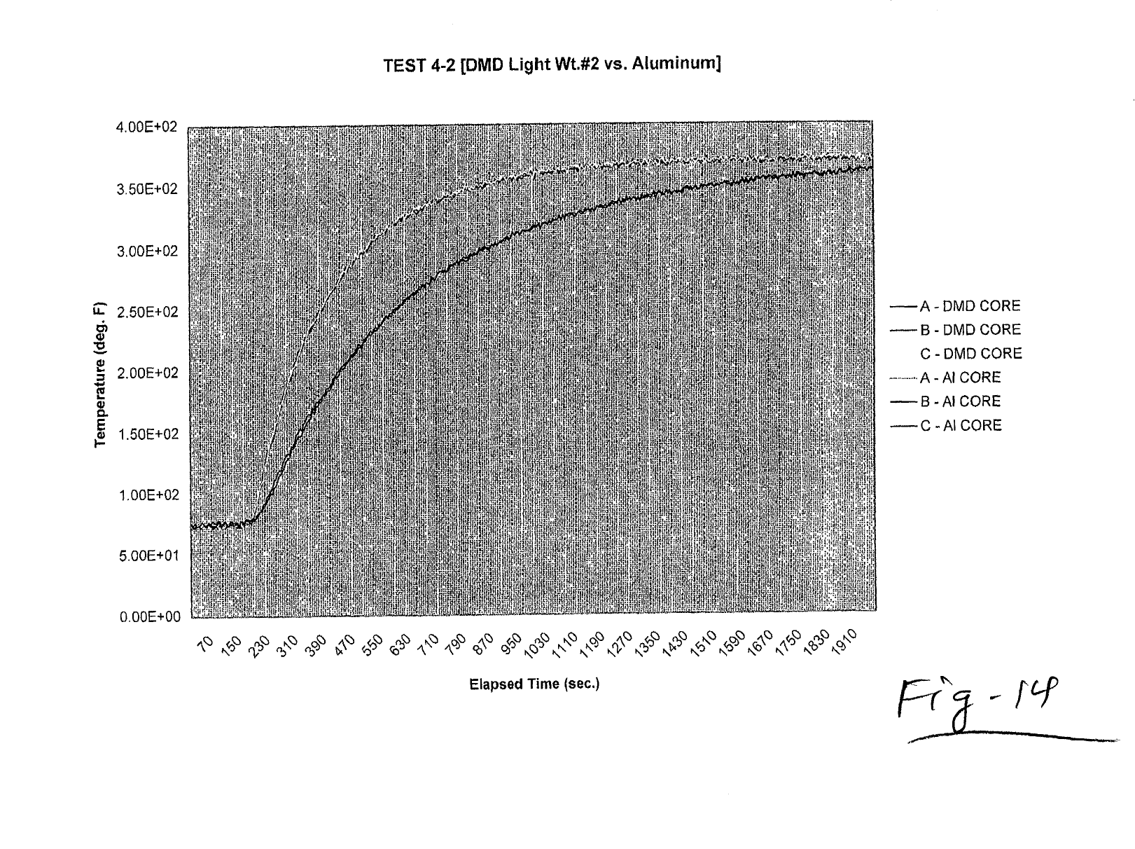

FIGS. 9 through 14, which plot temperature as function of thermal elapsed time show that dies designed for improved thermal management always provide rapid response compared to the industry standard aluminum dies which are also highly conductive. FIG. 9 plots temperature vs. elapsed time for aluminum vs. cavity structures produced using direct metal deposition. FIG. 10 plots temperature vs. elapsed time for aluminum vs. core structures produced using direct metal deposition. FIG. 11 is a plot of temperature vs. time for aluminum vs. lightweight cavity structures fabricated using direct metal deposition. FIG. 12 is a plot of temperature vs. time for aluminum vs. lightweight core structures fabricated using direct metal deposition. FIG. 13 is a plot of temperature vs. time for aluminum vs. a different lightweight structure fabricated using direct metal deposition with respect to cavity structures. FIG. 14 is a plot of temperature vs. time for aluminum vs. a different lightweight structure fabricated using direct metal deposition with respect to core structures.

### Example 3

### Fabrication of Lightweight Components

The non-equilibrium synthesis capabilities of CLDMD may also be utilized to fabricate lightweight tool and other components in accordance with this invention. For example, a light material such as aluminum may be used as substrate, with a wear-resistant material or high-temperature material being deposited with desired geometry and properties for the working surface. In one embodiment, a cast aluminum-silicon substrate with metallurgically bonded nickel alloy working surface is used for improved wear resistance. The metallurgical bond will also provide enhanced heat extraction. Another example is the integration of a steel working surface with an aluminum substrate, either with conformal cooling channels or highly conductive heat sinks such as copper or aluminum clad graphite.

Reconfiguration of large components is always a challenge. High mass makes accurate translation particularly difficult. For relatively flat surfaces, the problem can be overcome by moving the DMD optics system while keeping the tool stationary. However, if the tool needs deposition on curved surface away from the line of sight of the laser, then moving optics on gantry system will not be effective. To meet these particular challenges, the robotic implementation of the moving system is proposed. As shown in FIG. 3, the beam and material can be delivered in almost in any position of the object, with a robot and the material delivery system mounted on its wrist. Such a system will increase the flexibility of CLDMD even further to process stationary three-dimensional objects and add features within at least a 270° work envelop around the object.

We claim:

1. A method of fabricating a component having improved properties, comprising the steps of:
a) providing a substrate having a surface; and
b) depositing a layer of a material onto at least a portion of the surface of the substrate using a laser-assisted direct metal deposition process, wherein, compared to the substrate, the layer of material exhibits:
improved resistance to wear, corrosion, or oxidation,
improved thermal conduction,
greater density, or
a different phase.

2. The method of claim 1, wherein the material of the layer is specifically chosen to promote a phase which is different from that of the substrate.

3. The method of claim 1, further including the step of using non-equilibrium synthesis to dissolve a low-solubility material into the layer of material to increase its hardness.

4. The method of claim 1, wherein the step of providing a substrate having a surface includes the step of using direct metal deposition to build the substrate on an incremental basis.

5. The method of claim 1, wherein the substrate and layer comprise a die, mold or other tool.

6. The method of claim 1, further including the step of applying the layer of material using a robotic, closed-loop DMD arrangement.

7. A method of fabricating a component having improved properties, comprising the steps of:
a) providing a computer-aided design (CAD) description of the component to be fabricated;
b) using a laser-assisted, direct metal deposition (DMD) process in accordance with the CAD description to substantially fabricate the component having an outer surface; and
c) depositing a layer of a material having a desired characteristic onto at least a portion of the surface of the component, also using a laser-assisted direct metal deposition process.

8. The method of claim 7, wherein the layer of material exhibits improved wear resistance relative to the component.

9. The method of claim 7, wherein the layer of material is more thermally conductive than the component itself.

10. The method of claim 7, wherein the layer of material is more thermally conductive than the component itself.

11. The method of claim 7, wherein the layer of material has a density greater than that of the component itself.

12. The method of claim 7, wherein the layer of material is more resistant to corrosion than the component itself.

13. The method of claim 7, wherein the layer of material is more resistant to oxidation than the component itself.

14. The method of claim 7, wherein the layer of material has a phase which is different from that of the component itself.

15. The method of claim 14, further including the step of choosing the material of the layer to promote a phase which is different from that of the substrate.

16. The method of claim 7, further including the step of using non-equilibrium synthesis to dissolve low a solubility material into the layer of material to increase hardness.

17. The method of claim 7, wherein the component is a die, mold or other tool.

18. The method of claim 7, further including the step of applying the layer of material using a robotic closed-loop DMD arrangement.

19. The method of claim 7, further including the step of incorporating one or more conformal cooling channels within the component during its fabrication.

20. The method of claim 7, further including the step of incorporating one or more conductive heat sinks or thermal barriers during its fabrication.
